(19) United States
(12) Patent Application Publication
(10) Pub. No.: US 2026/0304612 A1
(43) Pub. Date: Oct. 1, 2026

(54) WIRING BOARD

(71) Applicant: KYOCERA CORPORATION, Kyoto-SHI, Kyoto (JP)

(72) Inventors: Hiroaki SANO, Kirishima-shi, Kagoshima (JP); Katsuya URABE, Kirishima-shi, Kagoshima (JP); Michinobu NAKAMIYA, Kirishima-shi, Kagoshima (JP); Masanori OKAMOTO, Kirishima-shi, Kagoshima (JP); Akira IMOTO, Kirishima-shi, Kagoshima (JP); Sentarou YAMAOTO, Kirishima-shi, Kagoshima (JP)

(73) Assignee: KYOCERA CORPORATION, Kyoto-shi, Kyoto (JP)

(21) Appl. No.: 19/478,407

(22) PCT Filed: Apr. 24, 2024
(86) PCT No.: PCT/JP2024/016078

§ 371 Date: Oct. 24, 2025

(30) Foreign Application Priority Data
Apr. 26, 2023 (JP) 2023-072537

(51) Int. Cl. H05K 1/03

(52) U.S. Cl. CPC H05K 1/0306; H05K 2201/017

(57) ABSTRACT

A wiring board includes an insulation base and a conductor layer. In the insulation base a plurality of ceramic insulation layers are layered and integrated. The insulation base includes an inorganic coating film on a peripheral edge portion of the insulation base.

### CROSS-REFERENCE TO RELATED APPLICATIONS

This application is a national stage application of International Application No. PCT/JP 2024/016078, filed on Apr. 24, 2024, which designates the United States, the entire contents of which are herein incorporated by reference, and which is based upon and claims the benefit of priority to Japanese Patent Application No. 2023-072537, filed on Apr. 26, 2023, the entire contents of which are herein incorporated by reference.

### TECHNICAL FIELD

Embodiments of the present disclosure relates to a wiring board.

### BACKGROUND

In recent years, a highly layered type wiring board has been proposed in which a plurality of ceramic base materials are used to form a multilayer structure and a wiring line is disposed between the layers.

### CITATION LIST

### Patent Literature

Patent Document 1: WO 2005/067359

### SUMMARY

A wiring board according to an aspect of an embodiment includes an insulation base and conductor layers. In the insulation base, a plurality of ceramic insulation layers are layered and integrated. The insulation base includes an inorganic coating film on a peripheral edge portion of the insulation base.

### BRIEF DESCRIPTION OF THE DRAWINGS

FIG. 1A is a perspective view illustrating an example of a wiring board according to a first embodiment.

FIG. 1B is a cross-sectional view taken along line A-A in FIG. 1A.

FIG. 2A is a perspective view illustrating an example of a ceramic insulation layer included in the wiring board according to the first embodiment.

FIG. 2B is a cross-sectional view taken along line B-B in FIG. 2A.

FIG. 3 is a cross-sectional view illustrating an example of a wiring board according to a second embodiment.

FIG. 4 is an enlarged view illustrating a part of the wiring board illustrated in FIG. 3.

FIG. 5 is a plan view illustrating an example of a wiring board according to a third embodiment.

FIG. 6 is a cross-sectional view illustrating an example of the wiring board according to the third embodiment.

FIG. 7 is a plan view illustrating an example of a wiring board according to a fourth embodiment.

FIG. 8 is a plan view illustrating an example of a method for manufacturing the wiring board illustrated in FIG. 7.

FIG. 9 is a cross-sectional view illustrating an example of a wiring board according to a fifth embodiment.

FIG. 10 is a cross-sectional view taken along line X-X in FIG. 9.

FIG. 11 is a cross-sectional view illustrating an example of a wiring board according to a sixth embodiment.

FIG. 12 is a cross-sectional view illustrating an example of a wiring board according to a seventh embodiment.

FIG. 13 is a cross-sectional view illustrating an example of a wiring board according to an eighth embodiment.

### DETAILED DESCRIPTION

The above-described wiring board has room for enhancement in terms of increasing thermal shock resistance of a multilayered wiring board.

In this regard, a wiring board that can enhance thermal shock resistance is expected to be provided.

Modes (hereinafter, referred to as “embodiments”) for implementing a wiring board according to the present disclosure are described in detail below with reference to the drawings. Note that the wiring board according to the present disclosure is not limited to the embodiments. The embodiments can be appropriately combined within a range so as not to contradict each other in terms of processing content. Note that in the following description, the same reference signs are used for identical or similar components, and detailed descriptions thereof are omitted.

In recent years, in addition to the high definition of a wiring line accompanying miniaturization and pitch narrowing, the necessity of increasing the area of a solid GND (ground) in a wiring board has been increasing more and more. This is usually referred to as GND reinforcement or power supply reinforcement. In such a wiring board, the edge of the solid GND is extended to a position close to the lateral surface of the wiring board.

In such a wiring board having high definition, a large number of layers, and GND reinforcement, delamination and cracks are likely to occur on the lateral surface of the wiring board after heat treatment such as firing or solder reflow.

One object of the present disclosure is to obtain a wiring board having high thermal shock resistance, in which delamination and cracks are less likely to occur on a lateral surface of the wiring board. The delamination is a phenomenon in which two layered ceramic insulation layers are peeled off from each other. The delamination is likely to occur in a portion between two layered ceramic insulation layers. The crack refers to a broken portion generated in the ceramic insulation layer.

### First Embodiment

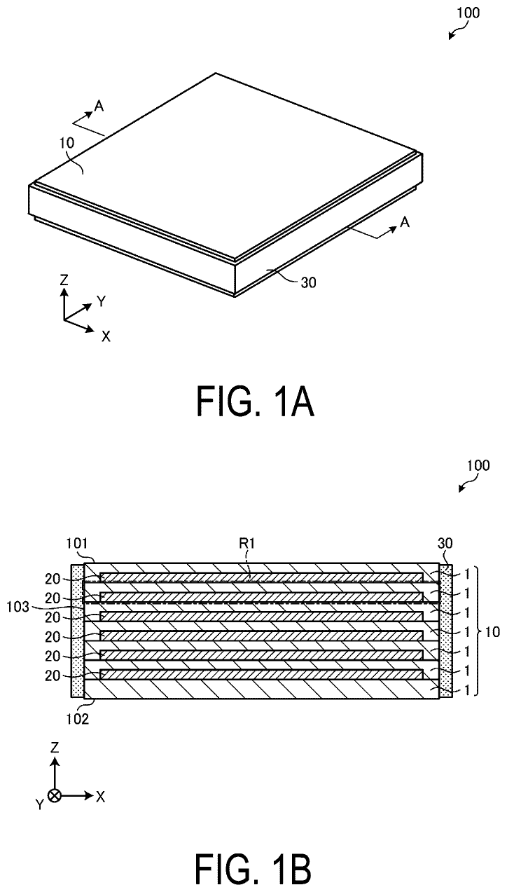

FIG. 1A is a perspective view illustrating an example of a wiring board according to a first embodiment. FIG. 1B is a cross-sectional view taken along line A-A in FIG. 1A. As illustrated in FIGS. 1A and 1B, a wiring board 100 according to the first embodiment includes an insulation base 10 and conductor layers 20.

The insulation base 10 includes a plurality of ceramic insulation layers 1. The insulation base 10 has a structure in which the plurality of ceramic insulation layers 1 are integrated. The insulation base 10 includes a first surface 101 and a second surface 102 located at both ends in a thickness direction (Z-axis direction). Although FIG. 1B illustrates an example in which the insulation base 10 includes seven ceramic insulation layers 1, the number of ceramic insulation layers 1 included in the insulation base 10 is not limited.

The ceramic insulation layer 1 may be, for example, glass ceramic. The glass ceramic may be any one of a composite of a glass phase and ceramic particles, a composite of a glass phase and a crystal phase formed by crystallization of a part of the glass phase, a form in which ceramic particles are present in a glass phase, and a form in which a glass phase is present at a grain boundary between ceramic particles. The ceramic insulation layer 1 is preferably made of, for example, a ceramic composition that can be co-fired with copper, as described below.

The conductor layers 20 are located between the ceramic insulation layers 1 that are layered. The conductor layer 20 may be located on the first surface 101 and/or the second surface 102 that are surfaces of the insulation base 10. The conductor layer 20 can be formed by firing a conductive paste containing copper powder, for example. The conductor layer 20 may be a metallized film of copper.

The insulation base 10 includes a coating film 30. The coating film 30 is inorganic. In this case, the coating film 30 is located at a peripheral edge portion 103AA to be described below of the insulation base 10. The coating film 30 may be located on at least a lateral surface 103 of the insulation base 10 located between the first surface 101 and the second surface 102.

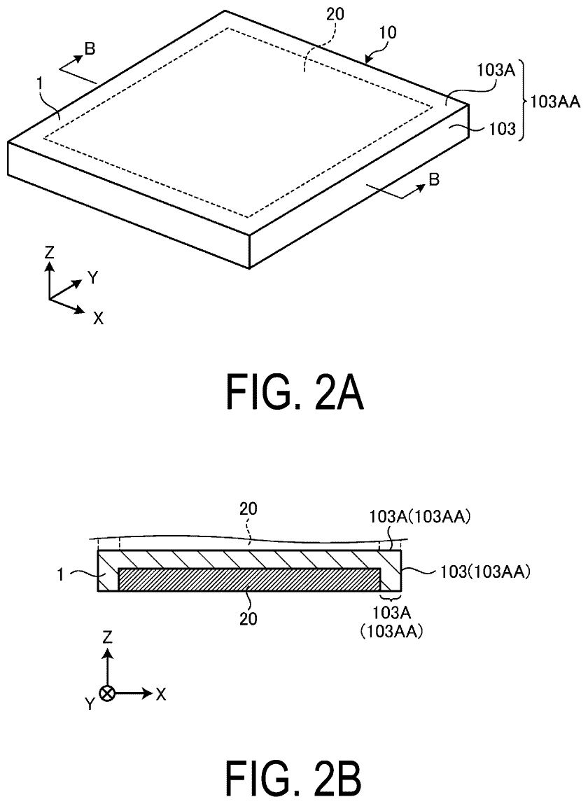

FIG. 2A is a perspective view illustrating an example of the ceramic insulation layer included in the wiring board according to the first embodiment. FIG. 2B is a cross-sectional view taken along line B-B in FIG. 2A. FIG. 2B corresponds to a region R1 illustrated in FIG. 1B.

As illustrated in FIGS. 2A and 2B, the peripheral edge portion 103AA of the insulation base 10 includes the lateral surface 103 of the insulation base 10 and is a portion extending from the lateral surface 103 to between the ceramic insulation layers 1 adjacent to each other in the layering direction of the insulation base 10.

In the insulation base 10, a portion extending between the ceramic insulation layers 1 adjacent to each other in the layering direction is defined as a peripheral edge region 103A. That is, the peripheral edge portion 103AA is a portion of the insulation base 10 in which the lateral surface 103 and the peripheral edge region 103A are combined.

The coating film 30 on the peripheral edge portion 103AA of the insulation base 10 can enhance the thermal impact resistance of the wiring board 100. For example, cracks are less likely to occur in the lateral surface 103 of the insulation base 10 and in the vicinity thereof. In addition, partial peeling is less likely to occur between two layered ceramic insulation layers 1.

As illustrated in FIG. 1B, the coating film 30 may be located to cover all the ceramic insulation layers 1 exposed on the lateral surface 103 of the insulation base 10. In this case, the coating film 30 mainly covers a so-called end surface portion of the ceramic insulation layer 1 exposed on the lateral surface 103 of the insulation base 10. In this case, the thermal shock resistance of the wiring board 100 can be further enhanced.

That is, cracks are less likely to occur in the lateral surface 103 of the insulation base 10 and in the vicinity thereof. In addition, in a portion between two layered ceramic insulation layers 1, partial peeling of the two layers is less likely to occur.

As described above, the coating film 30 used in the wiring board 100 is made of an inorganic material. Since the material of the coating film 30 is inorganic, the affinity with the insulation base 10 and the ceramic insulation layer 1 is high. The coating film 30 is preferably sintered and integrated with the insulation base 10 and the ceramic insulation layer 1. The coating film 30 and the insulation base 10 are preferably integrated with each other to such an extent that no linear interface is observed therebetween. The coating film 30 and each ceramic insulation layer 1 are also preferably integrated with each other to such an extent that no linear interface is observed therebetween.

The coating film 30 and the ceramic insulation layer 1 preferably contain a metal oxide containing Si, such as silica, in common. The coating film 30 and the ceramic insulation layer 1 are preferably in a state of being liquid-phase sintered therebetween.

The configurations illustrated in FIGS. 1A and 1B can be obtained by, for example, the following method. First, a pattern sheet having a conductor pattern formed on the surface of a green sheet is formed. Subsequently, a plurality of the pattern sheets are layered to form a layered body. Subsequently, a glass slurry to be the coating film 30 is applied to the lateral surface of the layered body. A method (dipping method) of immersing the lateral surface of the layered body in a glass slurry stored in a container may be used. Subsequently, the layered body applied with the glass slurry is fired.

The reason why delamination is likely to occur in the wiring board 100 is that, when the conductor pattern is formed on the surface of the green sheet, the pattern sheet has a step corresponding to the thickness of the conductor pattern with reference to the surface of the green sheet.

The conductor pattern is formed in a region of the surface of the green sheet excluding a peripheral edge region. In the peripheral edge region of the green sheet, a step is generated due to the thickness of the conductor pattern. When a plurality of pattern sheets originally having a step due to the thickness of the conductor pattern are layered, the step of each pattern sheet is accumulated in the layered body.

When such pattern sheets are layered, pressure and heat are applied. The green sheet constituting the pattern sheet contains an organic binder. Therefore, the green sheet exhibits thermoplasticity, and is deformed in a pressurization and heating process when the layered body is produced. The green sheet is deformed to fill the step caused by the thickness of the conductor pattern. However, when the number of layered pattern sheets is large, the bonding between the green sheets may be weakened in a portion close to the lateral surface of the layered body.

In addition, it is considered that delamination and cracks occurring in the wiring board 100 are caused by a stress generated by a difference in thermal expansion coefficient and a difference in Young's modulus based on a difference in material between the ceramic insulation layer 1 and the conductor layer 20.

It is considered that the stress generated between the ceramic insulation layer 1 and the conductor layer 20 tends to be concentrated at the peripheral edge of the conductor layer 20 in the wiring board 100. Since delamination is a behavior that occurs between two layered ceramic insulation layers 1, the lateral surface of the wiring board 100 or the insulation base 10, which is an open end of the wiring board 100, serves as a source of breakage.

The wiring board 100 of the present disclosure is provided with the coating film 30 integrally formed on the peripheral edge portion 103AA thereof with the same material as the insulation base 10. This can reduce the possibility that the lateral surface of the wiring board 100 or the insulation base 10, which is the open end of the wiring board 100, serves as a source of breakage.

### Second Embodiment

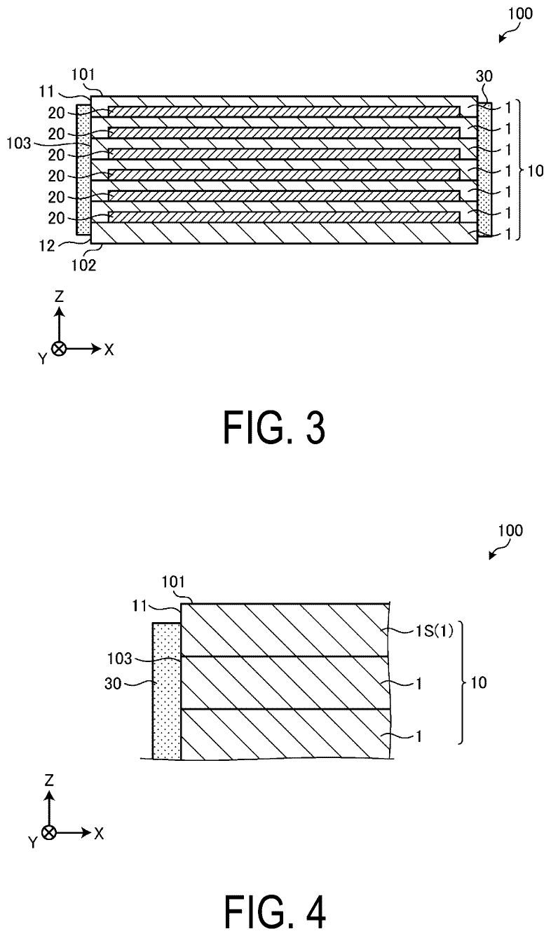

FIG. 3 is a cross-sectional view illustrating an example of a wiring board according to a second embodiment. FIG. 4 is enlarged view illustrating a part of the wiring board illustrated in FIG. 3.

As illustrated in FIG. 3, an insulation base 10 may include exposed portions 11 and 12 where a coating film 30 is not located, in the lateral surface of a ceramic insulation layer 1 located at the outermost layer. The exposed portions 11 and 12 are portions of a lateral surface 103 of the insulation base 10 to which the coating film 30 is not bonded.

As illustrated in FIG. 4, the exposed portion 11 may be located on a first surface 101 side, which is a main surface, of a ceramic insulation layer 1S located at an end portion on a positive direction side of a Z axis. This makes it difficult for the flatness of the first surface 101 to decrease. Therefore, for example, a conductor layer 20 can be positioned near the peripheral edge of the first surface 101.

The exposed portion 12 may be located on a second surface 102 side, which is a main surface, of the ceramic insulation layer 1 located at an end portion on a negative direction side of the Z axis. This makes it difficult for the flatness of the second surface 102 to decrease. Therefore, for example, the conductor layer 20 can be positioned near the peripheral edge of the second surface 102.

The configuration illustrated in FIG. 3 can be produced by, for example, dipping a layered body, in which the ceramic insulation layers 1 are layered, by using a glass slurry that is a material of the coating film 30. In this case, the exposed portions 11 and 12 of the layered body where the coating film 30 is not formed are masked with a tape or the like so that the glass slurry is less likely to adhere thereto. The tape is preferably peeled off before degreasing and firing. The insulation base 10 may have only one of the exposed portions 11 and 12.

### Third Embodiment

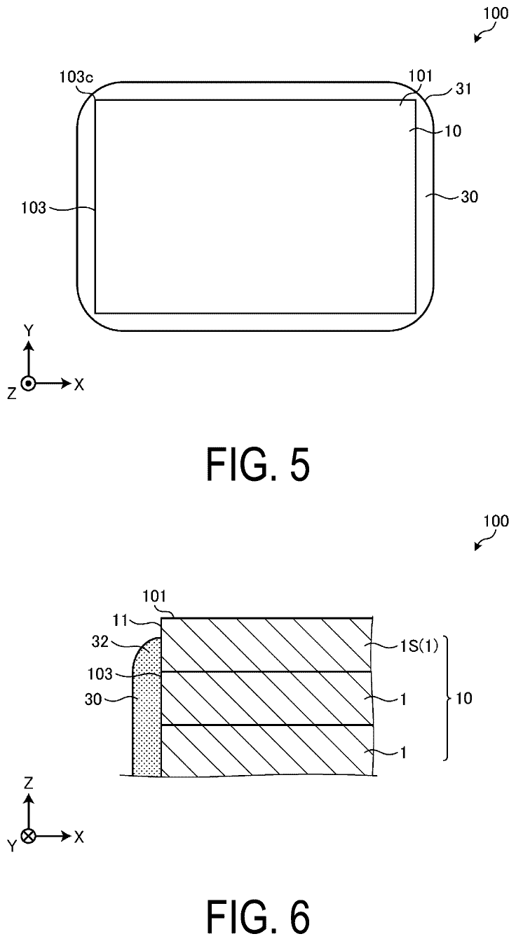

FIG. 5 is a plan view illustrating an example of a wiring board according to a third embodiment. FIG. 6 is a cross-sectional view illustrating an example of the wiring board according to the third embodiment.

As illustrated in FIG. 5, a coating film 30 may be located to surround the entire circumference of a lateral surface 103 of an insulation base 10. Thus, in a wiring board 100, peeling or cracking of a ceramic insulation layer 1 is less likely to occur over the entire circumference of the lateral surface 103.

As illustrated in FIG. 5, the thickness of the coating film 30 covering a corner portion 103c, where the lateral surfaces 103 of adjacent insulation bases 10 intersect each other, may be smaller than the thickness of the coating film 30 located on the lateral surface 103 excluding the corner portion 103c. The outline of a corner portion 31 of the coating film 30 covering the corner portion 103c may be rounded.

The corner portion 103c is more likely to be chipped when coming into contact with other structures or the like than a side (or ridge) portion located between two corner portions 103c, but when the thickness of the coating film 30 at the corner portion 103c is made smaller than the thickness of the side (or ridge) portion, the coating film 30 at the corner portion 103c is less likely to be chipped and the aesthetic appearance of a product can be less likely to be impaired.

As illustrated in FIG. 6, the coating film 30 may have a shape in which the thickness of an end portion 32 close to a first surface 101 gradually decreases toward the first surface 101. An end portion 32 of the coating film 30 may be rounded.

The shape of the coating film 30 in the Z direction (vertical direction) of the insulation base 10 is also preferably rounded rather than angular. Also in this case, the coating film 30 is less likely to be chipped, and the aesthetic appearance of the wiring board 100 is easily maintained.

### Fourth Embodiment

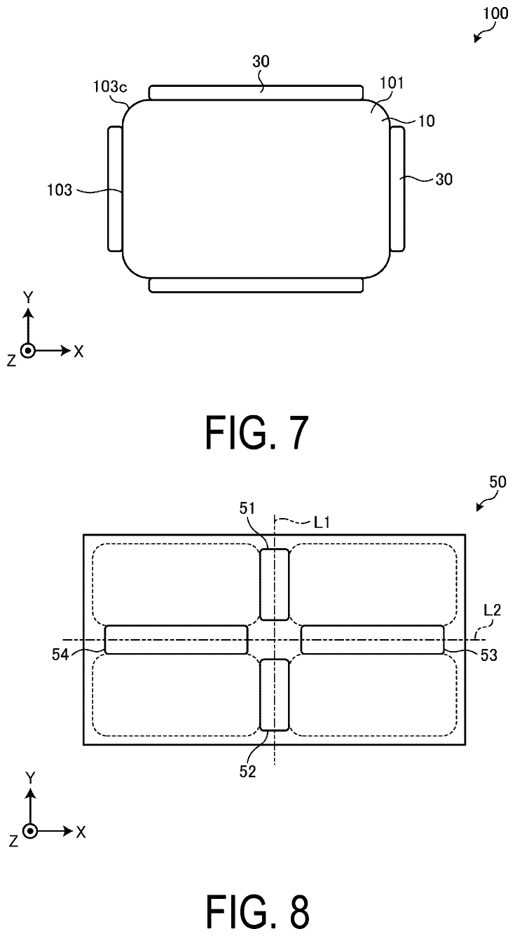

FIG. 7 is a plan view illustrating an example of a wiring board according to a fourth embodiment. As illustrated in FIG. 7, an insulation base 10 may have a rounded corner portion 103c located between adjacent lateral surfaces 103. A coating film 30 may be located on the lateral surface 103 of the insulation base 10 excluding the rounded corner portion 103c. This makes it difficult for the insulation base 10 to be chipped at the corner portion 103c due to the coating film 30.

A wiring board 100 illustrated in FIG. 7 can be produced as follows. FIG. 8 is a plan view illustrating an example of a method for manufacturing the wiring board illustrated in FIG. 7.

The plan view illustrated in FIG. 8 illustrates a green layered body 50. The green layered body 50 has a size that allows a plurality of insulation bases 10, which are the bases of the wiring board 100 described above, to be produced. The green layered body 50 illustrated in FIG. 8 has a size capable of taking four wiring boards 100 (or insulation bases 10). The green layered body 50 is a layered body that can be formed into a large number of pieces, not limited to four pieces.

First, the green layered body 50 having such a shape is prepared. Subsequently, a plurality of through holes 51 to 54 penetrating in the thickness direction (Z-axis direction) are provided in the green layered body 50. As illustrated in FIG. 8, the through holes 51 to 54 are formed so that layered bodies cut out from the green layered body 50 do not fall apart. The layered body referred to herein corresponds to the insulation base 10. That is, in the case of the present disclosure, the through holes 51 to 54 are processed to be able to maintain a connected state between corner portions of adjacent layered bodies (insulation bases 10 below) in the green layered body 50.

Subsequently, a glass slurry to be the coating film 30 is poured into the through holes 51 to 54 formed in the green layered body 50, and is solidified by performing a drying process. Subsequently, the green layered body 50 is cut along lines L1 and L2, thereby obtaining a layered body to be the wiring board 100. Subsequently, the produced layered body is fired. In this way, a plurality of wiring boards 100 are obtained. The wiring board 100 illustrated in FIG. 7 may be produced by any method, not limited to the method illustrated in FIG. 8.

For example, a method is used in which the green layered body 50 is cut to obtain a plurality of layered bodies, the plurality of layered bodies are disposed in a frame separately prepared, and then the glass slurry is poured. In this case, the plurality of layered bodies are disposed at predetermined intervals in the frame. Referring to FIG. 8, the structure of the frame may be, for example, a shape obtained by hollowing out a portion of the layered body indicated by a broken line and portions corresponding to the through holes 51 to 54 indicated by thick solid rectangles from the rectangular plan view of the green layered body 50 illustrated in FIG. 8.

### Fifth Embodiment

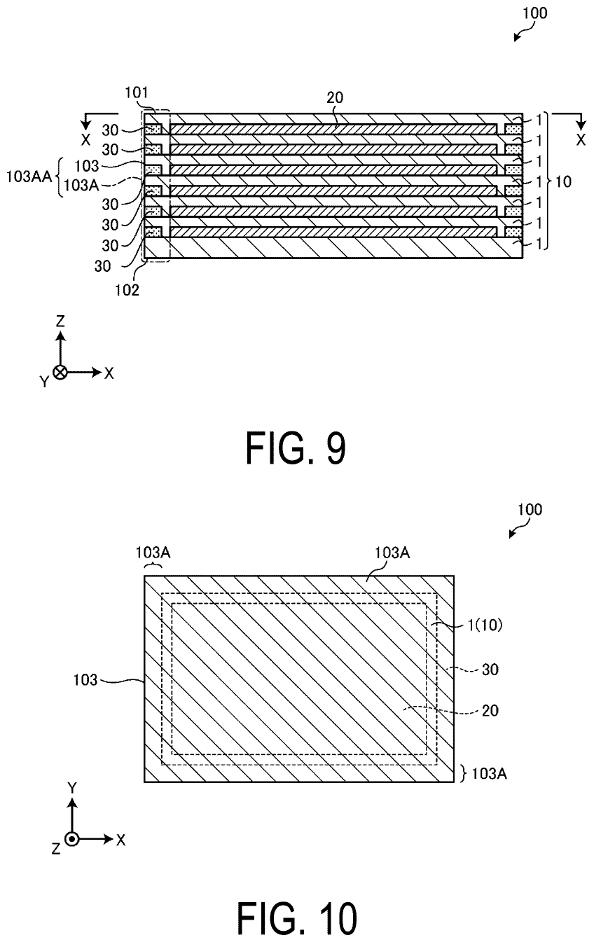

FIG. 9 is a cross-sectional view illustrating an example of a wiring board according to a fifth embodiment. FIG. 10 is a cross-sectional view taken along line X-X in FIG. 9. FIG. 10 illustrates a state when the surface of a conductor layer 20 located under the uppermost ceramic insulation layer 1 is seen through in plan view when a wiring board 100 illustrated in FIG. 9 is viewed from above (positive Z direction side). A peripheral edge region 103A of the present disclosure is a frame-shaped portion corresponding to the arrangement of a coating film 30 illustrated in FIG. 10.

As illustrated in FIG. 9, in the wiring board 100, the coating film 30 may be located in a peripheral edge portion 103AA of the insulation base 10 and between two ceramic insulation layers 1 adjacent to each other in the layering direction. Thus, in the wiring board 100, the ceramic insulation layer 1 in the insulation base 10 is less likely to peel off or crack.

In this case, the peripheral edge portion 103AA is a range including a peripheral edge region 103A of each ceramic insulation layer 1 constituting the insulation base 10. The coating film 30 has a thickness corresponding to the thickness of a conductor layer 20 formed on the ceramic insulation layer 1, and may have a thickness to such an extent that the step of the conductor layer 20 is eliminated.

Although FIGS. 9 and 10 illustrate a state in which the coating film 30 and the conductor layer 20 are spaced apart from each other at a predetermined interval on the surface of the ceramic insulation layer 1, the present disclosure is not limited thereto and the coating film 30 and the conductor layer 20 may be in contact with each other. When the coating film 30 and the conductor layer 20 are spaced apart from each other on the surface of the ceramic insulation layer 1, a part of the ceramic insulation layer 1 preferably enters the gap between the coating film 30 and the conductor layer 20 to form a dense state. This can enhance mechanical strength of the insulation base 10.

In this case, the coating film 30 may be located in a peripheral edge region 103A of the ceramic insulation layer 1 constituting the insulation base 10. In particular, the coating film 30 may be located to surround the peripheral edge region 103A of the ceramic insulation layer 1 constituting the insulation base 10. This makes it difficult for the insulation base 10 to peel off between two layered ceramic insulation layers 1 in the wiring board 100. In addition, according to the present configuration, cracks are less likely to occur in the insulation base 10 and the ceramic insulation layers 1.

### Sixth Embodiment

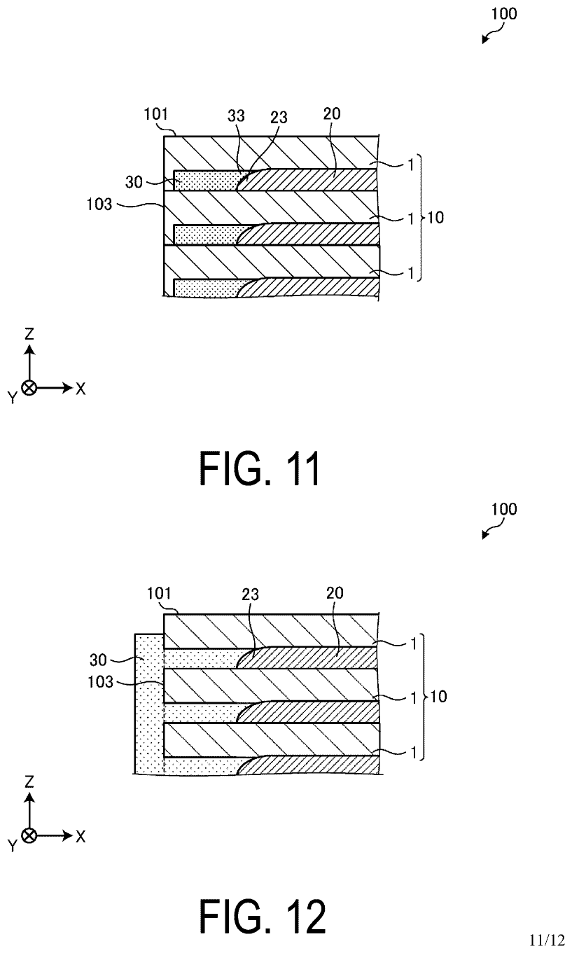

FIG. 11 is a cross-sectional view illustrating an example of a wiring board according to a sixth embodiment. As illustrated in FIG. 11, a conductor layer 20 may include an end portion 23 whose thickness gradually decreases toward a lateral surface 103 of an insulation base 10. A coating film 30 may include a portion 33 overlapping the conductor layer 20 in the thickness direction. This makes it difficult for the end portion 23 of the conductor layer 20 to peel off from the ceramic insulation layer 1.

As illustrated in FIG. 11, the coating film 30 may not reach the lateral surface 103 of the insulation base 10 and may not be exposed on the lateral surface 103. Thus, the lateral surface 103 of the insulation base 10 has a function of protecting the coating film 30 located inside the insulation base 10, with a part of the ceramic insulation layer 1 integrally connecting the layers in the layering direction. In this way, a wiring board 100 (or the insulation base 10) having high mechanical strength can be obtained.

### Seventh Embodiment

FIG. 12 is a cross-sectional view illustrating an example of a wiring board according to a seventh embodiment. As illustrated in FIG. 12, a coating film 30 may extend from a portion along a lateral surface 103 of an insulation base 10 to the inside. This increases the contact area between the coating film 30 and the insulation base 10, so that the ceramic insulation layer 1 is less likely to peel off.

The coating film 30 illustrated in FIG. 12 has a structure in which the coating film 30 is continuously integrated between ceramic insulation layers 1 from the lateral surface 103 of the insulation base 10. In this case, the coating film 30 has a comb-like structure (shape) when the insulation base 10 is viewed in vertical cross section. That is, when the coating film 30 has a comb-like structure in the layering direction, since the coating film 30 is connected in the layering direction of the insulation base 10 and is integrated, the mechanical strength of the coating film 30 itself can be enhanced.

In addition, when the coating film 30 is a structure having such a shape, the adhesive force of the coating film 30 to the lateral surface 103 of the insulation base 10 is increased. In addition, the coating film 30 can be firmly bonded to the insulation base 10 over an entire peripheral edge portion 103AA including the lateral surface 103 and a peripheral edge region 103A of the insulation base 10.

### Eighth Embodiment

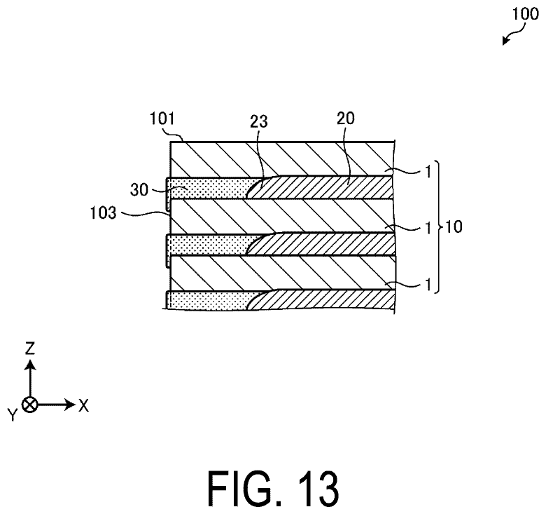

FIG. 13 is a cross-sectional view illustrating an example of a wiring board according to an eighth embodiment. A coating film 30 illustrated in FIG. 13 has a smaller volume of a portion provided on a lateral surface 103 of an insulation base 10 than the coating film 30 illustrated in FIG. 12. The coating film 30 located on the lateral surface 103 may not be connected in the layering direction and may cover a part of an end surface of each ceramic insulation layer 1.

When the coating film 30 has the structure as illustrated in FIG. 13, the thickness and volume of the coating film 30 at the lateral surface 103 are reduced, which contributes to reduction in volume and weight of a wiring board 100. Also in this case, two layered ceramic insulation layers 1 in the insulation base 10 can be prevented from being peeled off from each other, and the possibility of occurrence of cracks in the ceramic insulation layers 1 can be reduced.

In FIGS. 12 and 13, the coating film 30 is in contact with an end portion 23 of a conductor layer 20, but the conductor layer 20 and the coating film 30 may be partially separated from each other. In this case, the ceramic insulation layer 1 may partially enter the gap between the conductor layer 20 and the coating film 30. This can reduce a decrease in the density of the insulation base 10.

### Other Embodiments

As described above, glass ceramic can be used as a suitable material for the ceramic insulation layer 1. Therefore, a vitreous material is more suitable as the material of the coating film 30. This allows the material of the coating film 30 to have a lower Young's modulus than the material of the ceramic insulation layer 1. For example, when the wiring board 100 (insulation base 10) receives an external force, the coating film 30 serves as a buffer material, so that the wiring board 100 is less likely to be damaged.

In addition, when the Young's modulus of the material of the coating film 30 is lower than the Young's modulus of the material of the insulation base 10 or the ceramic insulation layer 1, in view of the situation in which the coating film 30 is in contact with both the conductor layer 20 and the ceramic insulation layer 1, the stress generated between the conductor layer 20 and the ceramic insulation layer 1 is more likely to be further relaxed.

The glass ceramic as the material of the ceramic insulation layer 1 may have an inorganic filler. On the other hand, the coating film 30 may not have an inorganic filler. The inorganic filler refers to, for example, a particulate inorganic material having a maximum diameter of 3 μm or more.

In each of the above-described embodiments, the insulation base 10 may be glass ceramic containing a filler. The coating film 30 may have a lower filler content than the insulation base 10.

In each of the above-described embodiments, the coating film 30 may have a lower softening point than the ceramic insulation layer 1. The softening points of the coating film 30 and the ceramic insulation layer 1 can be measured by a DSC method. This indicates the characteristics (softening point) of the glass slurry used for forming the coating film 30 with respect to the solid content.

For example, in the case where the softening point of the solid content contained in the glass slurry applied to the layered body and the green sheet is lower than the softening point of the solid content contained in the green sheet when the insulation base 10 is formed, the glass slurry to be the coating film 30 is sintered at a lower temperature than the layered body (green sheet) when the layered body is fired. Therefore, in the layered body in which the glass slurry is applied to the lateral surface and the inside, the peripheral edge portion 103AA of the insulation base 10 receives a binding force by the coating film 30 based on the glass slurry during sintering. As a result, the peripheral edge portion 103AA of the insulation base 10 (or the wiring board 100) is less likely to be deformed irregularly during the fixing.

### EXAMPLE

### Producing of Samples

First, a green sheet (100 mm×100 mm ×thickness 200 μm) containing a material powder of glass ceramic was prepared. The raw material powder of the glass ceramic was a mixed powder of borosilicate glass and silica particles. Specifically, a mixed powder obtained by adding 50 parts by mass of silica particles to 100 parts by mass of borosilicate glass was used. A butyral-based organic resin was used as an organic vehicle for the green sheet.

A mixture of copper powder and borosilicate glass powder was used as a conductive paste for a conductor layer. As the organic vehicle, a cellulose-based organic resin was used. As the solid content, a composition in which 30 parts by mass of borosilicate glass powder was added to 100 parts by mass of copper powder was adopted.

Subsequently, a glass paste for forming a coating film was prepared. As the organic vehicle, a cellulose-based organic resin was used. The softening point of the glass powder used for the glass paste was 500° C. The softening point of the glass powder used for the green sheet was 700° C. When the softening points are the same, the softening point may be changed depending on the presence or absence of an inorganic filler.

The conductive paste was printed in a so-called solid state on a central region of the green sheet except for a peripheral edge region (3 mm) to form a conductor pattern (expression before firing). The thickness of the conductor pattern was about 20 μm.

Subsequently, the glass paste with the conductor pattern formed thereon was printed on the peripheral edge portion of the green sheet, thereby producing a pattern sheet having a glass pattern. The thickness of the glass pattern was set to be equal to the thickness of the conductor pattern. The thickness of an end portion of the conductor pattern tends to gradually decrease. As the glass pattern, two types of patterns, that is, a type of glass pattern not overlapping the conductor pattern (for example, see FIG. 9) and a type of glass pattern overlapping the conductor pattern (for example, see FIG. 11) were respectively produced.

After a plurality of pattern sheets (30 layers) were layered, a solid green sheet having neither a conductor pattern nor a glass pattern formed thereon was layered on the uppermost layer, and the layered body was pressurized and heated (30 MPa, 100° C., 10 minutes) to produce a layered body.

The size of the layered body was about 100 mm x 100 mm x 7 mm. The firing was performed by degreasing in a wet nitrogen atmosphere, and then holding in a dry nitrogen atmosphere at a maximum temperature of 950° C. for 2 hours.

Ten samples of the wiring board were produced for each of the type not overlapping the conductor pattern and the type overlapping the conductor pattern. A sample in which the pressure at the time of layering was set to 40 MPa was also produced in the same manner. In this sample, the glass pattern protruded from the lateral surface of the layered body for each layer (when the lateral surface of the layered body was viewed, the glass pattern protruded upward and downward from the center between the layers of the layered green sheets to such an extent that the glass patterns do not come into contact with each other between the layers).

Moreover, a layered body was produced using a pattern sheet on which no glass paste was printed, and 10 samples were also produced in which the glass paste was applied to the lateral surface of the layered body (the glass application was performed by a method of immersing the edge of the layered body in a glass slurry contained in a container). A protective tape was partially attached to the main surface of the outermost green sheet so that the glass paste is not attached thereto. The coating film of the glass paste had a shape in which the thickness gradually decreases toward an end corresponding to the corner of the layered body (insulation base).

As a comparative example, ten samples of the same size were produced in which no glass paste was printed on a portion to be a peripheral edge portion of an insulator (sample 1). As a comparative example, a wiring board having a size of 10 mm×10 mm (the same thickness) on which no glass paste was printed was also produced in the same manner (sample 2). The ratio of an area of the conductor pattern to an area of the green sheet was the same as the ratio in the case of 100 mm×100 mm.

### Results

In the sample (sample 1) of 100 mm×100 mm in which no glass paste was printed on the portion to be the peripheral edge portion of the insulator, peeling was observed on the lateral surface of the wiring board in all of the ten samples. The peeling occurred near the middle stage in the layering direction.

In the sample (sample 2) of 10 mm×10 mm in which no glass paste was printed, peeling was observed on the lateral surface of the wiring board in five of the ten samples. The peeling occurred near the middle stage in the layering direction.

However, no delamination was observed after firing in 10 samples of the type in which the glass pattern did not overlap the conductor pattern (sample 3: corresponding to FIGS. 9) and 10 samples of the type in which the glass pattern overlapped the conductor pattern (sample 4: corresponding to FIG. 11).

In particular, in the sample (sample 4) in which the glass patterns overlapped, no peeling (delamination) was observed on the lateral surface of the wiring board even in a heat resistance test in which the sample of the wiring board was immersed for 1 second in a solder bath heated to 330° C. In addition, no cracks were observed in the ceramic insulation layer of sample 4.

In the solder heat resistance test under the same conditions, delamination was observed in one (sample 3) of ten samples in which the glass pattern did not overlap the conductor pattern. In the wiring board of the sample 3 in which delamination was observed, cracks were observed in a part of the ceramic insulation layer of the wiring board.

In the sample (sample 5) in which the pressure at the time of layering was set to 40 MPa, no peeling (delamination) of the wiring board was observed after the solder heat resistance test after firing. No cracks were observed in the ceramic insulation layer. In the sample 5, when the lateral surface of the insulation base was viewed, the coating films 30 were in a state of protruding upward and downward from the center between the layers of the layered ceramic insulation layers to such an extent that the coating films 30 do not come into contact with each other between the layers.

Moreover, in the sample (sample 6) in which the glass paste was not printed on the surface of the green sheet and was applied only to the lateral surface of the layered body, no delamination was observed in all of the ten samples after the firing and after the solder heat resistance test.

While the present disclosure has been described in detail, the present disclosure is not limited to the aforementioned embodiments, and various changes, improvements, and the like can be made without departing from the gist of the present disclosure.

In an embodiment, (1) A wiring board includes: an insulation base in which a plurality of ceramic insulation layers are layered and integrated; and a conductor layer; wherein the insulation base includes an inorganic coating film on a peripheral edge portion of the insulation base.

(2) In the wiring board according to (1), the coating film may be located on a lateral surface of the insulation base.

(3) In the wiring board according to (1), the coating film may be located to cover all layers on a lateral surface of the insulation base.

(4) In the wiring board according to any one of (1) to (3), the insulation base may include an exposed portion on a main surface side of a lateral surface of the ceramic insulation layer located at an outermost layer, the coating film not being located on the exposed portion.

(5) In the wiring board according to any one of (1) to (4), the coating film may be located to surround an entire perimeter of the lateral surface of the insulation base.

(6) In the wiring board according to (1), the insulation base may include rounded corner portions between adjacent lateral surfaces, and the coating film may be located on a lateral surface of the insulation base excluding the corner portions.

(7) In the wiring board according to (1), the coating film may be located in the peripheral edge portion and between two ceramic insulation layers adjacent to each other in a layering direction.

(8) In the wiring board according to (7), an average thickness of the coating film may be smaller than an average thickness of the conductor layer.

(9) In the wiring board according to (1), the conductor layer may include an end portion having a thickness gradually decreasing toward a peripheral edge of the insulation base, and the coating film may include a portion overlapping the conductor layer in a thickness direction.

(10) In the wiring board according to any one of (1) to (9), a material of the ceramic insulation layer may be glass ceramic, and a material of the coating film may be glass.

(11) In the wiring board according to any one of (1) to (9), the insulation base may be glass ceramic containing a filler, and the coating film may have a smaller content of the filler than the insulation base.

(12) In the wiring board according to any one of (1) to (11), the coating film may have a lower softening point than the ceramic insulation layer.

(13) In the wiring board of (1), the coating film may extend inward from a portion along a lateral surface of the insulation base.

(14) In the wiring board of (1), the coating film may be located to extend from between layers of the insulation base to a lateral surface of the insulation base.

Additional effects and other aspects can be easily derived by one skilled in the art. Thus, the broader aspects of the present disclosure are not limited to the specific details and representative embodiments illustrated and described above. Accordingly, various changes can be made without departing from the spirit or scope of the general inventive concepts defined by the appended claims and their equivalents.

### REFERENCE SIGNS

1 Ceramic insulation layer
10 Insulation base
20 Conductor layer
30 Coating film
100 Wiring board

1. A wiring board comprising:
an insulation base in which a plurality of ceramic insulation layers are layered and integrated; and
a conductor layer; wherein
the insulation base includes an inorganic coating film on a peripheral edge portion of the insulation base.

2. The wiring board according to claim 1, wherein the coating film is located on a lateral surface of the insulation base.

3. The wiring board according to claim 1, wherein the coating film is located to cover all layers on a lateral surface of the insulation base.

4. The wiring board according to claim 1, wherein
the insulation base includes an exposed portion on a main surface side of a lateral surface of the ceramic insulation layer located at an outermost layer, the coating film not being located on the exposed portion.

5. The wiring board according to claim 1, wherein
the coating film is located to surround an entire perimeter of the lateral surface of the insulation base.

6. The wiring board according to claim 1, wherein
the insulation base includes rounded corner portions between adjacent lateral surfaces, and
the coating film is located on a lateral surface of the insulation base excluding the corner portions.

7. The wiring board according to claim 1, wherein
the coating film is located in the peripheral edge portion and between two ceramic insulation layers adjacent to each other in a layering direction.

8. The wiring board according to claim 7, wherein
an average thickness of the coating film is smaller than an average thickness of the conductor layer.

9. The wiring board according to claim 1, wherein
the conductor layer includes an end portion having a thickness gradually decreasing toward a peripheral edge of the insulation base, and
the coating film includes a portion overlapping the conductor layer in a thickness direction.

10. The wiring board according to claim 1, wherein
a material of the ceramic insulation layer is glass ceramic, and
a material of the coating film is glass.

11. The wiring board according to claim 1, wherein
the insulation base is glass ceramic containing a filler, and
the coating film has a smaller content of the filler than the insulation base.

12. The wiring board according to claim 1, wherein
the coating film has a lower softening point than the ceramic insulation layer.

13. The wiring board according to claim 1, wherein
the coating film extends inward from a portion along a lateral surface of the insulation base.

14. The wiring board according to claim 1, wherein
the coating film is located to extend from between layers of the insulation base to a lateral surface of the insulation base.

15. The wiring board according to claim 2, wherein
the coating film is located to surround an entire perimeter of the lateral surface of the insulation base.

16. The wiring board according to claim 3, wherein
the coating film is located to surround an entire perimeter of the lateral surface of the insulation base.

17. The wiring board according to claim 4, wherein
the coating film is located to surround an entire perimeter of the lateral surface of the insulation base.
